(19) United States
(12) Patent Application Publication
(10) Pub. No.: US 2023/0217738 A1
(43) Pub. Date: Jul. 6, 2023

(54) DISPLAY PANEL AND DISPLAY APPARATUS

(71) Applicants: Wuhan Tianma Microelectronics Co., Ltd., Wuhan (CN); Wuhan Tianma Microelectronics Co., Ltd. Shanghai Branch, Shanghai (CN)

(72) Inventors: Qibing WEI, Wuhan (CN); Peng ZHANG, Wuhan (CN); Kang YANG, Wuhan (CN); Yuying CAI, Wuhan (CN)

(73) Assignees: Wuhan Tianma Microelectronics Co., Ltd., Wuhan (CN); Wuhan Tianma Microelectronics Co., Ltd. Shanghai Branch, Shanghai (CN)

(21) Appl. No.: 17/699,207

(22) Filed: Mar. 21, 2022

(30) Foreign Application Priority Data
Dec. 31, 2021 (CN) 202111675737.X

(51) Int. Cl. H01L 27/32

(52) U.S. Cl. CPC H01L 27/3276

(57) ABSTRACT

The embodiments of the present application provide a display panel and a display apparatus. The display panel includes: fan-out lines and a power signal line, and the power signal line includes openings; in a direction perpendicular to a plane in which the display panel is located, the fan-out lines include M fan-out line groups; the (i-1)-th fan-out line group includes the fan-out lines with a length Lᵢ₋₁, the i-th fan-out line group includes the fan-out lines with a length Lᵢ, the (i+1)-th fan-out line group includes the fan-out lines with a length Lᵢ₊₁, and Lᵢ₋₁>Lᵢ>Lᵢ₊₁; overlapping areas between the power signal line and the fan-out lines with the length Lᵢ₋₁, Lᵢ and Lᵢ₊₁ are Sᵢ₋₁, Sᵢ and Sᵢ₊₁, respectively, Sᵢ₋₁≥Sᵢ≥Sᵢ₊₁, and 2 ≤i≤M−1.

### CROSS-REFFERENCE TO RELATED APPLICATION

This application claims priority to Chinese Patent Application No. 202111675737.X, filed on Dec. 31, 2021, which is incorporated herein by reference in its entirety.

### TECHNICAL FIELD

The present application relates to the field of display technology, and particularly to a display panel and a display apparatus.

### BACKGROUND

With the development of display technology, the types of display panels are becoming more and more extensive. For example, the display panels may include Liquid Crystal Display (LCD) panel, Organic Light Emitting Diode (OLED) display panel, Sub-millimeter Light Emitting Diode (Mini LED) display panel and Micro Light Emitting Diode (Micro LED) display panel, etc.

Nonetheless, the current display panels have problems of poor encapsulating effect and/or display effect.

### SUMMARY

The embodiments of the present application provide a display panel and a display apparatus.

In a first aspect, the embodiments of the present application provide a display panel including a display area, and fan-out lines and a power signal line located in a non-display area, the power signal line includes openings overlapping at least a part of the fan-out lines; in a direction perpendicular to a plane in which the display panel is located, the fan-out lines overlapping the power signal line include M fan-out line groups arranged in sequence along a first direction, each of the fan-out line groups includes at least one of the fan-out lines overlapping the power signal line, M is a positive integer; among the M fan-out line groups, a (i−1)-th fan-out line group is located at a side of an i-th fan-out line group away from the display area, a (i+1)-th fan-out line group is located at a side of the i-th fan-out line group close to the display area; the (i−1)-th fan-out line group includes the fan-out lines with a length Lᵢ₋₁, the i-th fan-out line group includes the fan-out lines with a length Lᵢ, the (i+1)-th fan-out line group includes the fan-out lines with a length Lᵢ₊₁, and >Lᵢ₋>Lᵢ₋₁; and in the direction perpendicular to the plane in which the display panel is located, an overlapping area between the fan-out lines with the length and the power signal line is an overlapping area between the fan-out lines with the length Lᵢ₋₁ and the power signal line is Sᵢ₋₁, and an overlapping area between the fan-out lines with the length Lᵢ₊₁ and the power signal line is Sᵢ₊₁, Sᵢ₋₁≥Sᵢ≥Sᵢ₊₁, in which 2≤i≤M−1.

In a second aspect, the embodiments of the present application provide a display apparatus including the display panel according to the first aspect.

### BRIEF DESCRIPTION OF THE DRAWINGS

In order to more clearly illustrate the technical solutions of the embodiments of the present application, the drawings to be used in the embodiments of the present application will be briefly introduced below. For those of ordinary skill in the art, other drawings can be obtained based on these drawings without inventive effort.

FIG. 1 shows a schematic top view of at least part of a display panel according to the embodiments of the present application;

FIG. 2 shows another schematic top view of at least part of a display panel according to the embodiments of the present application;

FIG. 3 shows a partial schematic top view of a display panel according to the embodiments of the present application;

FIG. 4 shows another partial schematic top view of a display panel according to the embodiments of the present application;

FIG. 5 shows yet another partial schematic top view of a display panel according to the embodiments of the present application;

FIG. 6 shows yet another partial schematic top view of a display panel according to the embodiments of the present application;

FIG. 7 shows a schematic top view of an opening on a power signal line in a display panel according to the embodiments of the present application;

FIG. 8 shows yet another partial schematic top view of a display panel according to the embodiments of the present application;

FIG. 9 shows another schematic top view of an opening on a power signal line in a display panel according to the embodiments of the present application;

FIG. 10 shows yet another partial schematic top view of a display panel according to the embodiments of the present application;

FIG. 11 shows yet another partial schematic top view of a display panel according to the embodiments of the present application;

FIG. 12 shows yet another partial schematic top view of a display panel according to the embodiments of the present application;

FIG. 13 shows yet another partial schematic top view of a display panel according to the embodiments of the present application;

FIG. 14 shows yet another partial schematic top view of a display panel according to the embodiments of the present application;

FIG. 15 shows yet another partial schematic top view of a display panel according to the embodiments of the present application;

FIG. 16 shows yet another partial schematic top view of a display panel according to the embodiments of the present application;

FIG. 17 shows yet another partial schematic top view of a display panel according to the embodiments of the present application;

FIG. 18 shows a schematic sectional view of the display panel shown in FIG. 17 along the direction A-A′;

FIG. 19 shows another schematic sectional view of the display panel shown in FIG. 17 along the direction A-A′;

FIG. 20 shows a partial schematic sectional view of a display area in a display panel according to the embodiments of the present application;

FIG. 21 shows a schematic graph of the capacitive impedances of the fan-out lines located at different locations of the display panel under a condition that the overlapping relationships between the fan-out lines and the openings on the power signal lines are not adjusted;

FIG. 22 shows a schematic graph of the capacitive impedances of the fan-out lines located at different locations of the display panel under a condition that the overlapping relationships between the fan-out lines and the openings on the power signal lines have been adjusted; and

FIG. 23 shows a schematic structural diagram of a display apparatus according to the embodiments of the present application.

### DETAILED DESCRIPTION

The features and exemplary embodiments of various aspects of the present application will be described in detail below. In order to make the objectives, technical solutions, and advantages of the present application clearer, the present application will be further described in detail below with reference to the drawings and specific embodiments. It should be understood that the specific embodiments described herein are merely intended to explain the present application, rather than to limit the present application. For those skilled in the art, the present application can be implemented without some of these specific details. The following description of the embodiments is merely to provide a better understanding of the present application by illustrating the examples of the present application.

It should be noted that, in the present application, relational terms, such as first and second, are used merely to distinguish one entity or operation from another entity or operation, without necessarily requiring or implying any actual such relationships or orders of these entities or operations. Moreover, the terms “comprise”, “include”, or any other variants thereof, are intended to represent a non-exclusive inclusion, such that a process, method, article or device including a series of elements includes not only those elements, but also other elements that are not explicitly listed or elements inherent to such a process, method, article or device. Without more constraints, the elements following an expression “comprise/include...” do not exclude the existence of additional identical elements in the process, method, article or device that includes the elements.

It should be understood that the term “and/or” used herein merely represents an association relationship for describing the associated entities, indicating that there may be three kinds of relationships, for example, A and/or B, which may indicate that A alone, both A and B, and B alone. In addition, the character “/” uses herein generally indicates that the associated entities before and after it are in an “or” relationship.

Since there are fabrication errors during the fabrication process of the display panel, such as the errors in etching, the embodiments of the present application describe the shapes of the openings or the positional relationships between different devices according to the idealized shapes or positional relationships. It should be understood that as long as the actual shapes of the openings are similar to the shapes of the openings mentioned in the embodiments of the present application, these actual shapes can be regarded as the shapes of the openings mentioned in the embodiments of the present application. For example, rectangles include rounded rectangles. The perpendicularity in the embodiments of the present application includes the perpendicularity allowed by the fabrication errors, and the parallelism in the embodiments of the present application includes the parallelism allowed by the fabrication errors.

In the embodiments of the present application, the term “electrically connected” may indicate that two components are directly electrically connected, or that the two components are electrically connected via one or more other components.

In the embodiments of the present application, the first node, the second node and the third node are only defined for convenience of describing the circuit structures, and the first node, the second node and the third node are not actual circuit units.

It is obvious to those skilled in the art that various modifications and variations can be made to the present application without departing from the gist or scope of the present application. Accordingly, the present application is intended to cover the modifications and variations to the present application that fall within the scope of the corresponding claims (the claimed technical solutions) and their equivalents. It should be noted that, the implementations provided in the embodiments of the present application may be combined with each other if there is no contradiction.

Before the technical solutions according to the embodiments of the present application are described, problems in the prior art are firstly specifically described to facilitate the understanding of the embodiments of the present application.

As described above, the inventor of the present application found that the display panel has technical problems of poor encapsulating effect and/or display effect.

In order to solve the above technical problems, the inventor of the present application firstly studied and analyzed the root causes of the above technical problems as follows.

The inventor of the present application found that stress is generated in the process of disposing frame sealant for the display panel (that is, the encapsulating process). On the one hand, if the generated stress cannot be released, the frame sealant will be deformed, causing the failure of the encapsulation, therefore the encapsulating effect of the display panel is poor. On the other hand, the generated stress will be applied to the power signal lines overlapping the frame sealant in the direction perpendicular to the plane in which the display panel is located, causing damage or even breakage of the power signal lines, therefore the display effect of the display panel is poor.

Based on the above findings of the inventor, the embodiments of the present application provide a display panel and a display apparatus, which are able to improve the encapsulating effect and the display effect of the display panel.

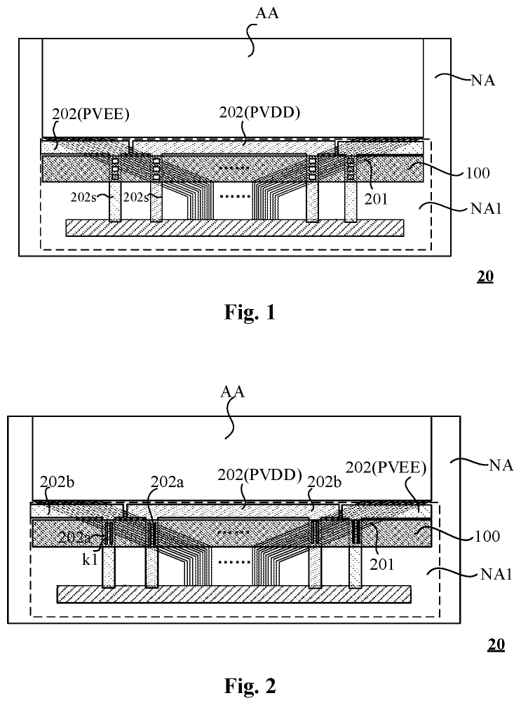

As shown in FIG. 1, the display panel 20 according to the embodiments of the present application may include a display area AA and a non-display area NA, and the non-display area NA may further include a step area NA1 located at a side of the display area AA. The fan-out lines 201 and the power signal lines 202 are arranged in the step area NA1. The fan-out lines 201 may be connected to the data signal line in the display area AA for transmitting the data signal Vdata. The power signal lines 202 may include a first power signal line PVDD and/or a second power signal line PVEE. Openings k1 are arranged on the power signal lines 202 (that is, the first power signal line PVDD and/or the second power signal line PVEE). The openings k1 may be located at least at locations where the power signal lines 202 overlap the encapsulating areas 100. The openings k1 arranged on the power signal lines 202 can release the stress generated in the encapsulating process, prevent the deformation of the frame sealant, and improve the encapsulating effect of the display panel. In addition, damage to the power signal lines 202 due to the stress generated in the encapsulating process can be avoided.

In addition, in order to reduce the size of the step area NA1 to obtain a narrow step, the inclination of the fan-out lines 201 can be set relatively large, so that most of the fan-out lines 201 can overlap the vertical structure 202s of the power signal lines 202.

The inventor of the present application further found that in the direction perpendicular to the plane in which the display panel 20 is located, the fan-out lines 201 located at different locations or adjacent locations may overlap different numbers or different areas of openings k1 on the power signal lines 202. As a result, the overlapping areas between the fan-out lines 201 located at different locations or adjacent locations and the power signal line 202 (the first power signal line PVDD and/or the second power signal line PVEE) may change abruptly, and moreover, the coupling capacitances generated between the fan-out lines 201 located at different locations or adjacent locations and the power signal line 202 may change abruptly, causing that the loads of the fan-out lines 201 change irregularly and the mura phenomenon occurs for the display panel, such as vertical stripes in the display panel.

Further, on the basis that the encapsulating effect of the display panel is improved, the embodiments of the present application may design the overlapping relationships between the fan-out lines and the openings on the power signal lines, so that the loads of the fan-out lines change monotonically and the display effect of the display panel is improved.

Specifically, by adjusting the overlapping relationships between the fan-out lines and the openings on the power signal lines, such as adjusting the location and/or size of the openings on the power-signal lines, or adjusting the routing of the fan-out lines, the overlapping areas between the power signal lines and the fan-out lines in the adjacent fan-out line groups are the same or decrease sequentially, so that the capacitive impedances generated between the power signal lines and the fan-out lines in the adjacent fan-out line groups are the same or change smoothly, therefore a sudden change of the capacitive impedances generated between the power signal lines and the fan-out lines located at different locations or adjacent locations is avoided. On the basis that the encapsulating effect of the display panel is improved, the mura phenomenon of the display panel is reduced or even eliminated, and the display effect of the display panel is improved.

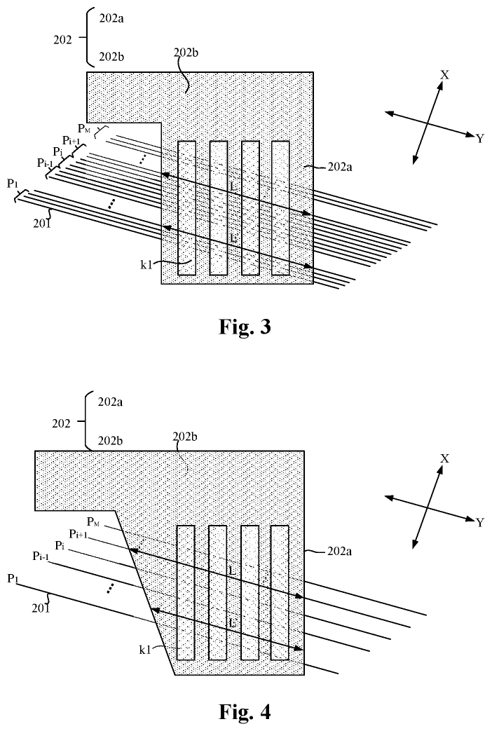

The display panel according to the embodiments of the present application will be described in detail below with reference to FIG. 2 and FIG. 3.

First, it should be noted that the structures of the display panel 20 in the embodiments of the present application as shown in the above FIG. 1 and the following FIG. 2 are only schematic and does not limit the embodiments of the present application. For example, the shape and routing of the first power signal line PVDD, the second power signal line PVEE and the fan-out lines 201 in FIG. 1 or FIG. 2 may be changed arbitrarily, and the number and location of the bonding pad, the number and location of the driver chip in the display panel 20 may be changed arbitrarily.

As shown in FIG. 2 and FIG. 3, the display panel 20 according to the embodiments of the present application includes the display area AA, and the fan-out lines 201 and the power signal lines 202 located in the non-display area NA. Exemplarily, the non-display area NA may include the step area NA1 located at a side of the display area AA, and the fan-out lines 201 and the power signal lines 202 are arranged in the step area NA1. The fan-out lines 201 may be connected to the data signal line in the display area AA for transmitting the data signal Vdata. The power signal lines 202 may include the first power signal line PVDD and/or the second power signal line PVEE. It may be understood that the first power signal line PVDD can be used to provide a positive voltage signal, for example, a voltage signal of 4.6 V or other positive voltage values. The second power signal line PVEE can be used to provide a negative voltage signal, for example, a voltage signal of −4.6 V or other negative voltage values.

The power signal line 202 include openings k1 overlapping at least a part of the fan-out lines 201, which can release the stress generated in the encapsulating process, so as to prevent the power signal line 202 from breaking due to the stress. It should be noted that, unless otherwise specified, the “overlap” used in the embodiments of the present application refers to the overlap of different components in the direction perpendicular to the plane in which the display panel 20 is located. That is, the power signal line 202 include openings k1 overlapping at least a part of the fan-out lines 201 in the direction perpendicular to the plane in which the display panel 20 is located. Herein, the plane in which the display panel 20 is located may include the light-emitting surface (display surface) or the back1ight surface of the display panel 20. In addition, it should be noted that the openings k1 are not limited to the first section 202a in the power signal line 202 that overlaps the encapsulating area 100, but may be alternatively located at other sections of the power signal line 202 other than the first section 202a. For example, the openings k1 may be alternatively located at the second section 202b of the power signal line 202, and the distribution locations of the openings k1 are not limited in the embodiments of the present application.

Still referring to FIG. 3, in the direction perpendicular to the plane in which the display panel 20 is located, the fan-out lines 201 overlapping the power signal line 202 include M fan-out line groups P arranged in sequence along a first direction X, each of the fan-out line groups P includes at least one of the fan-out lines 201 overlapping the power signal line 202, and M is a positive integer. For convenience of illustration, the M fan-out line groups P as shown are represented by P₁˜P_{M}, respectively. For example, Pi represents the first fan-out group P, Pᵢ represents the i-th fan-out group P, and P_{M} represents the M-th fan-out group P. Exemplarily, the “the fan-out lines 201 overlapping the power signal line 202” herein may specifically refer to the fan-out lines 201 overlapping the section corresponding to the openings k1 on the power signal line 202 (such as the first section 202a0. In addition, each of the fan-out line groups P includes at least one of the fan-out lines 201, it may be understood that each of the fan-out line groups P includes one fan-out line 201 or a plurality of fan-out lines 201. For example, FIG. 3 exemplarily shows that each of the fan-out line groups P includes three fan-out lines 201, and FIG. 4 exemplarily shows that each of the fan-out line groups P includes one fan-out line 201. It may be understood that each of the fan-out line groups P may alternatively include other numbers of the fan-out lines 201 other than one or three, such as two fan-out lines 201, ten fan-out lines 201 or other numbers of fan-out lines 201. In addition, the numbers of the fan-out lines 201 in different fan-out line groups P may be the same or different, which is not limited in the embodiments of the present application.

Among the M fan-out line groups P, the (i−1)-th fan-out line group P is located at a side of the i-th fan-out line group P away from the display area AA, and the (i+1)-th fan-out line group P is located at a side of the i-th fan-out line group P close to the display area AA. Herein, the i-th fan-out line group P is any one of the M fan-out line groups P, and 2≤i≤M−1. For example, when i=2, the first fan-out line group P is located at a side of the second fan-out line group P away from the display area AA, and the third fan-out line group P is located at a side of the second fan-out line group P close to the display area AA. The (i−1)-th fan-out line group P includes the fan-out lines 201 with a length the i-th fan-out line group P includes the fan-out lines 201 with a length Li, the (i+1)-th fan-out line group P includes the fan-out lines 201 with a length Lᵢ₊₁, and Lᵢ₊₁.

It should be noted that if each of the fan-out line groups P includes a plurality of the fan-out lines 201, the lengths of the plurality of the fan-out lines 201 in the fan-out line group P may be the same or different. Taking the (i−1)-th fan-out line group P as an example, if the (i−1)-th fan-out line group P includes a plurality of the fan-out lines 201, the lengths of the plurality of the fan-out lines 201 in the (i−1)-th fan-out line group P may be the same, for example, Lᵢ₋₁. Alternatively, the lengths of the plurality of the fan-out lines 201 in the (i−1)-th fan-out line group P may be different. If the lengths of the plurality of the fan-out lines 201 in the (i−1)-th fan-out line group P are different, for example, the average length of the plurality of the fan-out lines 201 in the (i−1)-th fan-out line group P may be Lᵢ₋₁, or the length of the longest fan-out line 201 in the (i−1)-th fan-out line group P may be Lᵢ₋₁, or the length of the shortest fan-out line 201 in the (i−1)-th fan-out line group P may be L₋₁. The same is true for the i-th fan-out line group P and the (i+1)-th fan-out line group P. In some embodiments, for example, the length of the shortest fan-out line 201 in the (i−1)-th fan-out line group P may be greater than the length of the longest fan-out line 201 in the i-th fan-out line group P, and the length of the shortest fan-out line 201 in the i-th fan-out line group P may be greater than the length of the longest fan-out line 201 in the (i+1)-th fan-out line group P. In the embodiments of the present application, the length of the fan-out line 201 may refer to the total length of the fan-out line 201 in the step area NA1. For example, the length of the fan-out line 201 may refer to the length from the connection point between the fan-out line 201 and the data signal line to the bonding pad bounded by the fan-out line 201.

In the direction perpendicular to the plane in which the display panel is located, an overlapping area between the fan-out lines 201 with the length Lᵢ₋₁ (i.e., the fan-out lines 201 in the (i−1)-th fan-out line group P) and the power signal line 202 is Si-i, an overlapping area between the fan-out lines 201 with the length Li (i.e., the fan-out lines 201 in the i-th fan-out line group P) and the power signal line 202 is Si, and an overlapping area between the fan-out lines 210 with the length Li+i (i.e., the fan-out lines 201 in the (i+1)-th fan-out line group P) and the power signal line 202 is Sᵢ₊₁, and Sᵢ₋₁≥Sᵢ≥Sᵢ₊₁.

It may be understood that in the direction perpendicular to the plane in which the display panel is located, as the overlapping areas between the fan-out lines 201 and the openings k1 increase, the overlapping areas between the fan-out lines 201 and the power signal line 202 decrease instead. Therefore, by adjusting the overlapping relationships between the fan-out lines 201 and the openings k1 on the power signal line 202, the overlapping areas between the power signal line 202 and the fan-out lines 201 in the (i−1)-th fan-out line group P, the i-th fan-out line group P and the (i+1)-th fan-out line group P satisfy Sᵢ₋₁≥Sᵢ≥Sᵢ₊₁.

In some specific embodiments, the overlapping areas between the power signal line 202 and the fan-out lines 201 in the (i−1)-th fan-out line group P, the i-th fan-out line group P and the (i+1)-th fan-out line group P may satisfy Sᵢ₋₁=Sᵢ=Sᵢ₊₁. That is, the overlapping areas between the power signal line 202 and the fan-out lines 201 in the (i−1)-th fan-out line group P, the i-th fan-out line group P and the (i+1)-th fan-out line group P are the same. In this way, the capacitive impedances generated between the power signal line 202 and the fan-out lines 201 in the (i−1)-th fan-out line group P, the i-th fan-out line group P and the (i+1)-th fan-out line group P are the same, therefore a sudden change of the capacitive impedances generated between the fan-out lines located at different locations or adjacent locations and the power signal line is avoided, and the mura phenomenon of the display panel is reduced or even eliminated.

Herein, it should be noted that due to the influence of material factors, the fan-out lines 201 themselves have impedance, which is referred to as resistive impedance for distinction. It may be understood that the resistive impedance of the fan-out line 201 will increase as the length of the fan-out line increases. Therefore, the resistive impedances of the fan-out lines 201 in the (i−1)-th fan-out line group P, the i-th fan-out line group P and the (i+1)-th fan-out line group P are different, for example, decrease sequentially. In order to facilitate the understanding, the resistive impedance of the fan-out lines in the (i−1)-th fan-out line group P is represented by R1, the resistive impedance of the fan-out lines in the i-th fan-out line group P is represented by R2, and the resistive impedance of the fan-out lines in the (i+1)-th fan-out line group P is represented by R3. Since Lᵢ₊₁>Lᵢ>Lᵢ₊₁, R1>R2>R3. If R1, R2 and R3 change smoothly, the human eye usually cannot observe the mura phenomenon of the display panel, which can be regarded as there is no mura phenomenon. Since the capacitive impedances Rc generated between the power signal line 202 and the fan-out lines 201 in the (i−1)-th fan-out line group P, the i-th fan-out line group P and the (i+1)-th fan-out line group P are the same, R1+Rc>R2+Rc>R3+Rc, that is, the total impedances (the sum of the resistive impedance and the capacitive impedance) of the fan-out lines 201 in the adjacent fan-out line groups P still change smoothly, therefore the human eye cannot observe the mura phenomenon of the display panel.

In some other specific embodiments, the overlapping areas between the power signal line 202 and the fan-out lines 201 in the (i−1)-th fan-out line group P, the i-th fan-out line group P and the (i+1)-th fan-out line group P may satisfy Sᵢ₋₁>Sᵢ>Sᵢ₊₁. That is, the overlapping areas between the power signal line 202 and the fan-out lines 201 in the (i−1)-th fan-out line group P, the i-th fan-out line group P and the (i+1)-th fan-out line group P decrease sequentially. In this way, the capacitive impedances generated between the power signal line 202 and the fan-out lines 201 in the (i−1)-th fan-out line group P, the i-th fan-out line group P and the (i+1)-th fan-out line group P change smoothly, therefore a sudden change of the capacitive impedances generated between the fan-out lines located at different locations or adjacent locations and the power signal line is avoided, and the mura phenomenon of the display panel is reduced or even eliminated.

In order to facilitate the understanding, the resistive impedance of the fan-out lines in the (i−1)-th fan-out line group P is represented by R1, the resistive impedance of the fan-out lines in the i-th fan-out line group P is represented by R2, and the resistive impedance of the fan-out lines in the (i+1)-th fan-out line group P is represented by R3. Moreover, the capacitive impedance generated between the fan-out lines 201 in the (i−1)-th fan-out line group P and the power signal line 202 is represented by Rc1, the capacitive impedance generated between the fan-out lines 201 in the i-th fan-out line group P and the power signal line 202 is represented by Rc2, and the capacitive impedance generated between the fan-out lines 201 in the (i+1)-th fan-out line group P and the power signal line 202 is represented by Rc3. Since the overlapping areas satisfy Sᵢ₋₁>Sᵢ>Sᵢ₊₁, Rc1>Rc2>Rc3, that is, the capacitive impedances change smoothly. Since the lengths of the fan-out lines satisfy Lᵢ₋₁>Lᵢ>Lᵢ₊₁, R1>R2>R3. Therefore, the total impedances of the fan-out lines 201 satisfy R1+Rc1>R2+Rc2>R3+Rc3, that is, the total impedances (the sum of the resistive impedance and the capacitive impedance) of the fan-out lines 201 in the adjacent fan-out line groups P change smoothly, therefore the human eye cannot observe the mura phenomenon of the display panel.

According to the display panel 20 of the embodiments of the present application, the overlapping areas between the power signal line 202 and the fan-out lines 201 in the adjacent fan-out line groups P are the same or decrease sequentially, so that the capacitive impedances generated between the power signal line 202 and the fan-out lines 201 in the adjacent fan-out line groups P are the same or change smoothly, therefore a sudden change of the capacitive impedances generated between the fan-out lines 201 located at different locations or adjacent locations and the power signal line 202 is avoided, and the mura phenomenon of the display panel is reduced or even eliminated.

The display panel 20 will be described below with reference to some embodiments of the present application.

Still referring to FIG. 2 and FIG. 3, in some specific embodiments, optionally, among the M fan-out line groups P, the lengths of the fan-out lines 201 in the first fan-out line group P to the M-th fan-out line group P decrease sequentially. That is, the lengths of the fan-out lines 201 in the M fan-out line groups P change monotonically. In the direction perpendicular to the plane in which the display panel 20 is located, the overlapping areas between the power signal line 202 and the fan-out lines 201 in the first fan-out line group P to the M-th fan-out line group P are the same. For example, under a condition that the overlapping lengths L between the power signal line 202 and the fan-out lines 201 in the first fan-out line group P to the M-th fan-out line group P are equal, the overlapping lengths or overlapping areas between at least one of the openings k1 and the fan-out lines 201 in the first fan-out line group P to the M-th fan-out line group P may be equal, so that the overlapping areas between the power signal line 202 and the fan-out lines 201 in the first fan-out line group P to the M-th fan-out line group P are the same. Herein, the overlapping length may be the minimum distance along the second direction Y intersecting the first direction X.

As shown in FIG. 4, under a condition that the overlapping lengths L between the power signal line 202 and the fan-out lines 201 in the first fan-out line group P to the M-th fan-out line group P are not equal, the overlapping lengths or overlapping areas between at least one of the openings k1 and the fan-out lines 201 in the first fan-out line group P to the M-th fan-out line group P may also be not equal, so that the overlapping areas between the power signal line 202 and the fan-out lines 201 in the first fan-out line group P to the M-th fan-out line group P are the same.

In this way, since the overlapping areas between the power signal line 202 and the fan-out lines 201 in the first fan-out line group P to the M-th fan-out line group P are the same, the capacitive impedances generated between the power signal line 202 and the fan-out lines 201 in the first fan-out line group P to the M-th fan-out line group P are the same, therefore a sudden change of the capacitive impedances generated between the fan-out lines located at different locations or adjacent locations and the power signal line is avoided, so that the total impedances (the sum of the resistive impedance and the capacitive impedance) of the fan-out lines 201 in the first fan-out line group P to the M-th fan-out line group P change smoothly, and the mura phenomenon of the display panel is reduced or even eliminated.

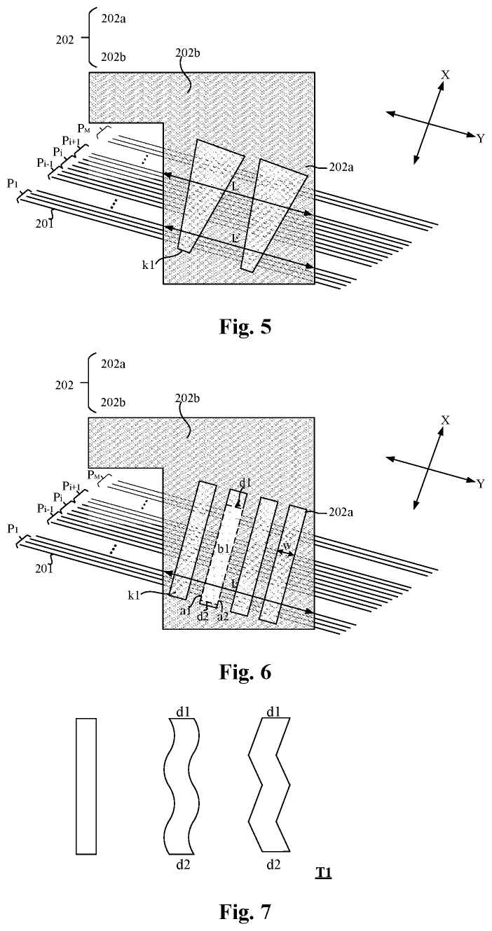

As shown in FIG. 5, in some other specific embodiments which are different from the embodiments of FIG. 3 and FIG. 4, optionally, in the direction perpendicular to the plane in which the display panel 20 is located, the overlapping areas between the power signal line 202 and the fan-out lines 201 in the first fan-out line group P to the M-th fan-out line group P decrease gradually.

In this way, since the overlapping areas between the power signal line 202 and the fan-out lines 201 in the first fan-out line group P to the M-th fan-out line group P decrease sequentially, the capacitive impedances generated between the power signal line 202 and the fan-out lines 201 in the first fan-out line group P to the M-th fan-out line group P change smoothly, therefore a sudden change of the capacitive impedances generated between the fan-out lines located at different locations or adjacent locations and the power signal line is avoided, so that the total impedances of the fan-out lines 201 in the first fan-out line group P to the M-th fan-out line group P change smoothly, and the mura phenomenon of the display panel is reduced or even eliminated.

In the embodiments of the present application, the shape, area and/or location of the opening k1 may be flexibly adjusted according to the actual situation, so that the overlapping areas between the power signal line 202 and the fan-out lines 201 in a plurality of the fan-out line groups P are the same or change smoothly. In order to facilitate the understanding, the following description make reference to some examples of the shape, area and/or location of the opening k1.

As shown in FIG. 6, according to some embodiments of the present application, optionally, the power signal line 202 may include Q openings which may extend along the first direction X, and Q is a positive integer. Exemplarily, Q may be 1 or an integer greater than 1. In the direction perpendicular to the plane in which the display panel 20 is located, all of the fan-out lines 201 in the M fan-out line groups P may overlap the Q openings. It should be noted that the fan-out line 201 can be regarded as overlap the opening k1 if the fan-out line 201 overlaps at least a portion of the opening k1. For example, if the fan-out line 201 only overlaps one corner of the opening k1, the fan-out line 201 may be regarded as overlap the opening k1. Along a direction from the (i+1)-th fan-out line group P to the (i−1)-th fan-out line group P, the width w of the opening k1 remain the same. Herein, the width w of the opening k1 may be the minimum distance of the opening k1 along the second direction Y intersecting the first direction X. The minimum distance may be interpreted as the minimum straight-line distance, or may be called the vertical distance. For example, if the shape of the opening k1 is a rectangle and the first edge and the second edge of the rectangle are perpendicular to the extension direction of the fan-out line 201, the width w of the opening k1 may be the length of the third edge or the fourth edge of the rectangle. Herein, the third edge of the rectangle is perpendicular to the first edge, and the fourth edge of the rectangle is opposite to the third edge of the rectangle.

In the embodiment shown in FIG. 6, since all of the fan-out lines 201 in the M fan-out line groups P overlap the Q openings k1 and the width of the Q openings k1 remain the same, the overlapping areas between the Q openings k1 and the fan-out lines 201 in the first fan-out line group P to the M-th fan-out line group P may be the same. Under a condition that the overlapping lengths L between the power signal line 202 and the fan-out lines 201 in the first fan-out line group P to the M-th fan-out line group P are equal, for example, when the first section 202a in the power signal line 202 that overlaps the encapsulating area is rectangular, the overlapping areas between the power signal line 202 and the fan-out lines 201 in the first fan-out line group P to the M-th fan-out line group P are the same, so that the display unevenness (the mura phenomenon) of the display panel is reduced or even eliminated. In addition, the openings with an elongated shape are more beneficial for adjusting the overlapping areas between the fan-out lines 201 and the power signal lines 202, which facilitates the implementation of the solutions.

Still referring to FIG. 6, according to some embodiments of the present application, optionally, in the direction perpendicular to the plane in which the display panel 20 is located, the fan-out lines 201 in the M fan-out line groups P may overlap a first portion b1 of each of the Q openings k1. The first portion b1 may be interpreted as at least a portion of the opening k1, for example, the first portion b1 may be the middle portion of the opening k1. Alternatively, in some examples, the first portion b1 may be the whole of the opening k1, that is, the entire opening k1 may be the first portion b1, which is not limited in the embodiments of the present application. It should be noted that in the direction perpendicular to the plane in which the display panel 20 is located, the shape of the first portion b1 of the opening k1 may include a first patterning with a constant width. As shown in FIG. 7, the first patterning T1 includes, but is not limited to, a rectangle, a wavy shape or a zigzag shape. It should be noted that the shape of the other portions of the opening k1 except the first portion b1 may be any shape, such as a circle, a rectangle, a triangle or an irregular shape.

In this way, since all of the fan-out lines 201 in the M fan-out line groups P overlap the first portion b1 of each of the Q openings k1 and the first portion b1 of the opening k1 is the first patterning with a constant width, the overlapping areas between the Q openings k1 and the fan-out lines 201 in the first fan-out line group P to the M-th fan-out line group P may be the same. Under a condition that the overlapping lengths L between the power signal line 202 and the fan-out lines 201 in the first fan-out line group P to the M-th fan-out line group P are equal, for example, when the first section 202a in the power signal line 202 that overlaps the encapsulating area is rectangular, the overlapping areas between the power signal line 202 and the fan-out lines 201 in the first fan-out line group P to the M-th fan-out line group P are the same, so that the mura phenomenon of the display panel is reduced or even eliminated.

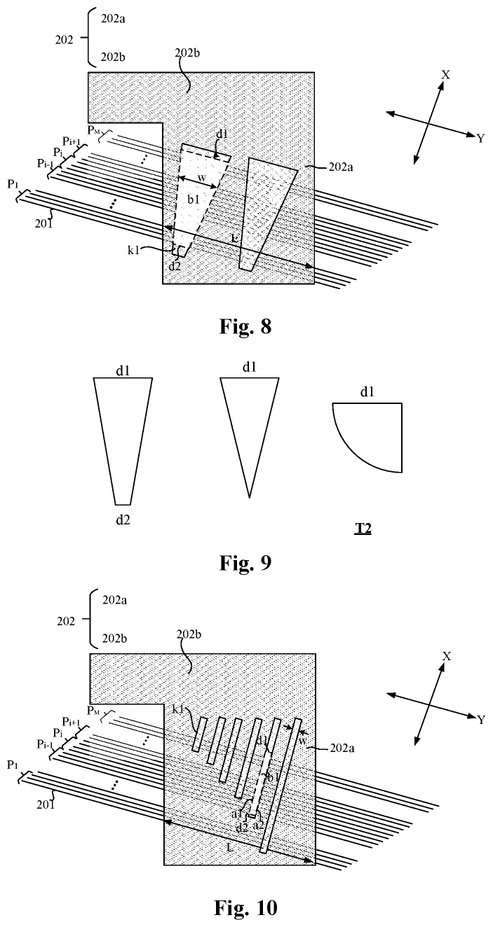

As shown in FIG. 8, according to some other embodiments of the present application which are different from the embodiments of FIG. 6, optionally, along the direction from the (i+1)-th fan-out line group P to the (i−1)-th fan-out line group P, the width w of the opening k1 may decrease gradually. Herein, the width w of the opening k1 may be the minimum distance of the opening k1 along the second direction Y intersecting the first direction X.

In the embodiment shown in FIG. 8, since all of the fan-out lines 201 in the M fan-out line groups P overlap the Q openings k1 and the width of the Q openings k1 changes gradually, the overlapping areas between the Q openings k1 and the fan-out lines 201 in the first fan-out line group P to the M-th fan-out line group P may increase gradually. Under a condition that the overlapping lengths L between the power signal line 202 and the fan-out lines 201 in the first fan-out line group P to the M-th fan-out line group P are equal, for example, when the first section 202a in the power signal line 202 that overlaps the encapsulating area is rectangular, the overlapping areas between the power signal line 202 and the fan-out lines 201 in the first fan-out line group P to the M-th fan-out line group P decrease gradually, so that the total impedances (the sum of the resistive impedance and the capacitive impedance) of the fan-out lines 201 in the first fan-out line group P to the M-th fan-out line group P change smoothly, and the mura phenomenon of the display panel is reduced or even eliminated. In addition, the openings with an elongated shape are more beneficial for adjusting the overlapping areas between the fan-out lines 201 and the power signal lines 202, which facilitates the implementation of the solutions.

As shown in FIG. 4, under a condition that the overlapping lengths L between the power signal line 202 and the fan-out lines 201 in the first fan-out line group P to the M-th fan-out line group P are not equal, for example, when the first section 202a in the power signal line 202 that overlaps the encapsulating area is inverted trapezoid, by gradually increasing the overlapping areas between the Q openings k1 and the fan-out lines 201 in the first fan-out line group P to the M-th fan-out line group P, the overlapping areas between the power signal line 202 and the fan-out lines 201 in the first fan-out line group P to the M-th fan-out line group P may be the same or decrease gradually, so that the total impedances (the sum of the resistive impedance and the capacitive impedance) of the fan-out lines 201 in the first fan-out line group P to the M-th fan-out line group P change smoothly, and the mura phenomenon of the display panel is reduced or even eliminated.

Still referring to FIG. 8, according to some embodiments of the present application, optionally, in the direction perpendicular to the plane in which the display panel 20 is located, the shape of the first portion b1 of the opening k1 may include a second patterning with a gradually decreasing width. As shown in FIG. 9, the second patterning T2 includes, but is not limited to, a trapezoid, a triangle or an arc. It should be noted that the shape of the other portions of the opening k1 except the first portion b1 may be any shape, such as a circle, a rectangle, a triangle or an irregular shape.

In this way, since all of the fan-out lines 201 in the M fan-out line groups P overlap the first portion b1 of each of the Q openings k1 and the first portion b1 of the opening k1 is the second patterning with a gradually decreasing width, the overlapping areas between the Q openings k1 and the fan-out lines 201 in the first fan-out line group P to the M-th fan-out line group P may increase gradually, so that the overlapping areas between the power signal line 202 and the fan-out lines 201 in the first fan-out line group P to the M-th fan-out line group P are the same or decrease gradually. As such, the total impedances (the sum of the resistive impedance and the capacitive impedance) of the fan-out lines 201 in the first fan-out line group P to the M-th fan-out line group P may change smoothly, and the mura phenomenon of the display panel is reduced or even eliminated.

As shown in FIG. 6, according to some embodiments of the present application, optionally, the shape of the first portion b1 of the opening k1 may be a rectangle. In the direction perpendicular to the plane in which the display panel 20 is located, the first portion b1 of the opening k1 includes a first edge a1 and a second edge a2 opposite to each other, and the extension direction of the first edge a1 and the second edge a2 may be perpendicular to the extension direction of the fan-out lines 201. For example, the extension direction of the first edge a1 and the second edge a2 is the first direction X, the extension direction of the fan-out lines 201 is the second direction Y, and the first direction X may be perpendicular to the second direction Y. It may be understood that in some other examples, alternatively, the first edge of the first portion b1 of the opening k1 may be the edge d1 as shown in FIG. 6, and the second edge of the first portion b1 of the opening k1 may be the edge d2 as shown in FIG. 6, and in such a case, the extension direction of the first edge d1 and the second edge d2 may be parallel to the extension direction of the fan-out lines 201.

In this way, if the shape of the first portion b1 of the opening k1 is a rectangle, the extension direction of a pair of edges of the first portion b1 is perpendicular to the extension direction of the fan-out lines 201, and the extension direction of the other pair of edges is parallel to the extension direction of the fan-out lines 201, so that the overlapping areas between the Q openings k1 and the fan-out lines 201 in the first fan-out line group P to the M-th fan-out line group P may be the same, which is beneficial for the adjustment the overlapping areas between the fan-out lines 201 and the power signal line 202 and the implementation of the solutions.

As shown in FIG. 7 and FIG. 9, it may be understood that if the shape of the first portion b1 of the opening k1 is a wavy shape or a zigzag shape, the extension direction of the first edge d1 and the second edge d2 opposite to each other of the wavy shape or the zigzag shape may be parallel to the extension direction of the fan-out lines. If the shape of the first portion b1 of the opening k1 is a trapezoid, the extension direction of the first edge d1 (the upper base) and the second edge d2 (the lower base) opposite to each other of the trapezoid may be parallel to the extension direction of the fan-out lines. If the shape of the first portion b1 of the opening k1 is a triangle, the extension direction of the first edge d1 of the triangle may be parallel to the extension direction of the fan-out lines. If the shape of the first portion b1 of the opening k1 is an arc, the extension direction of the straight edge d1 of the arc may be parallel to the extension direction of the fan-out lines. In this way, the adjustment of the overlapping areas between the fan-out lines 201 and the power signal line 202 can be improved, which facilitates the implementation of the solutions.

As shown in FIG. 10, according to some embodiments of the present application, optionally, the power signal line 202 may include P openings k1 which may extend along the first direction X, the P openings k1 may be arranged in sequence along the second direction Y intersecting the first direction X, and P is a positive integer. Exemplarily, P≥2. Along the second direction Y, the areas or lengths of at least a part of the P openings k1 may decrease gradually. It should be noted that, in some examples, the areas or lengths of all of the P openings k1 may decrease gradually. In some other examples, the areas or lengths of a part of the P openings k1 may decrease gradually, while the areas or lengths of another part of the P openings k1 may remain the same.

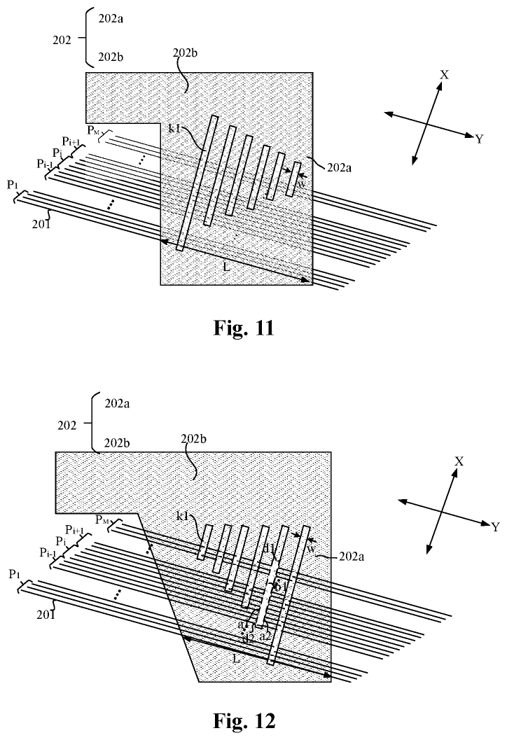

As shown in FIG. 11, according to some other embodiments of the present application which are different from the embodiment shown in FIG. 10, optionally, along the second direction Y, the areas or lengths of at least a part of the P openings k1 may increase gradually. For example, the areas or lengths of all of the P openings k1 may increase gradually, alternatively, the areas or lengths of only a part of the P openings k1 may increase gradually.

In this way, since the areas or lengths of at least a part of the P openings k1 decrease or increase gradually along the second direction, the number of openings k1 that can be overlapped by the fan-out lines 201 in the first fan-out line group P to the M-th fan-out line group P may be different, so that the overlapping areas between the power signal line 202 and the fan-out lines 201 in the first fan-out line group P to the M-th fan-out line group P may be different, for example, decrease sequentially.

In the embodiment shown in FIG. 10 or FIG. 11, the first section 202a of the power signal line 202 may be rectangular. The extension direction of the first edge a1 and the second edge a2 opposite to each other of the first section 202a may intersect the extension direction of the fan-out lines 201 in the M fan-out line groups P. Without considering the opening k1, the overlapping lengths L between the first section 202a of the power signal line 202 and the fan-out lines 201 in the first fan-out line group P to the M-th fan-out line group P are equal. Therefore, under a condition that the numbers of openings k1 overlapped by the fan-out lines 201 in the first fan-out line group P to the M-th fan-out line group P are different, the overlapping areas between the power signal line 202 and the fan-out lines 201 in the first fan-out line group P to the M-th fan-out line group P may decrease sequentially, so that the capacitive impedances and the total impedances (the sum of the resistive impedance and the capacitive impedance) of the fan-out lines 201 in the first fan-out line group P to the M-th fan-out line group P change smoothly, and the mura phenomenon of the display panel is reduced or even eliminated.

As shown in FIG. 12, according to some other embodiments of the present application, optionally, the first section 202a of the power signal line 202 may be inverted trapezoid. Without considering the opening k1, the overlapping lengths L between the first section 202a of the power signal line 202 and the fan-out lines 201 in the first fan-out line group P to the M-th fan-out line group P are not equal, for example, the overlapping lengths L between the first section 202a of the power signal line 202 and the fan-out lines 201 in the first fan-out line group P to the M-th fan-out line group P increase sequentially. As such, under a condition that the numbers of openings k1 overlapped by the fan-out lines 201 in the first fan-out line group P to the M-th fan-out line group P decrease sequentially, the overlapping areas between the power signal line 202 and the fan-out lines 201 in the first fan-out line group P to the M-th fan-out line group P may be the same or decrease sequentially, so that the capacitive impedances and the total impedances (the sum of the resistive impedance and the capacitive impedance) of the fan-out lines 201 in the first fan-out line group P to the M-th fan-out line group P change smoothly, and the mura phenomenon of the display panel is reduced or even eliminated.

Still referring to FIG. 10, in some specific embodiments, optionally, along the direction from the (i+1)-th fan-out line group P to the (i−1)-th fan-out line group P, the width w of the opening k1 remains the same. Herein, the width w of the opening k1 may be the minimum distance of the opening k1 along the second direction Y intersecting the first direction X.

Still referring to FIG. 10, according to some embodiments of the present application, optionally, in the direction perpendicular to the plane in which the display panel 20 is located, the shape of the first portion b1 of the opening k1 may include a first patterning with a constant width. As shown in FIG. 7, the first patterning T1 includes, but is not limited to, a rectangle, a wavy shape or a zigzag shape. It should be noted that the shape of the other portions of the opening k1 except the first portion b1 may be any shape, such as a circle, a rectangle, a triangle or an irregular shape.

In this way, since the numbers of openings k1 overlapped by the fan-out lines 201 in the first fan-out line group P to the M-th fan-out line group P are different and the first portion b1 of the opening k1 is the first patterning with a constant width, the overlapping areas between the openings k1 and the fan-out lines 201 in the first fan-out line group P to the M-th fan-out line group P may be different, for example, increase sequentially, so that the overlapping areas between the power signal line 202 and the fan-out lines 201 in the first fan-out line group P to the M-th fan-out line group P decrease sequentially.

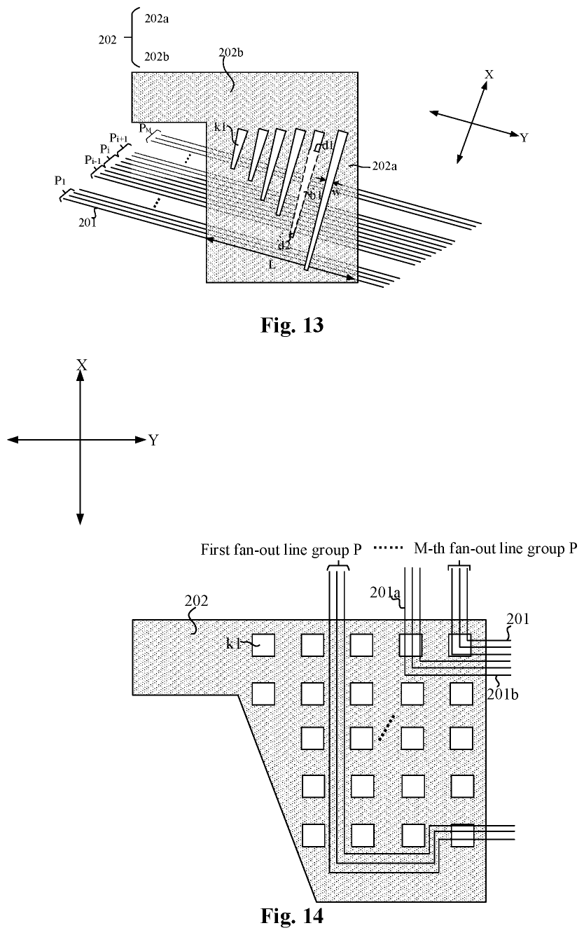

As shown in FIG. 13, according to some other embodiments of the present application which are different from the embodiments of FIG. 10, optionally, along the direction from the (i+1)-th fan-out line group P to the (i−1)-th fan-out line group P, the width w of the opening k1 may decrease gradually. Herein, the width w of the opening k1 may be the minimum distance of the opening k1 along the second direction Y intersecting the first direction X.

In the embodiment shown in FIG. 13, since the numbers of openings k1 overlapped by the fan-out lines 201 in the first fan-out line group P to the M-th fan-out line group P are different and the width of the opening k1 changes gradually, the overlapping areas between the openings k1 and the fan-out lines 201 in the first fan-out line group P to the M-th fan-out line group P may increase gradually, so that the overlapping areas between the power signal line 202 and the fan-out lines 201 in the first fan-out line group P to the M-th fan-out line group P decrease sequentially. Under a condition that the overlapping lengths L between the power signal line 202 and the fan-out lines 201 in the first fan-out line group P to the M-th fan-out line group P are equal, for example, when the first section 202a in the power signal line 202 that overlaps the encapsulating area is rectangular, the overlapping areas between the power signal line 202 and the fan-out lines 201 in the first fan-out line group P to the M-th fan-out line group P decrease gradually, so that the total impedances (the sum of the resistive impedance and the capacitive impedance) of the fan-out lines 201 in the first fan-out line group P to the M-th fan-out line group P change smoothly, and the mura phenomenon of the display panel is reduced or even eliminated. In addition, the openings with an elongated shape are more beneficial for adjusting the overlapping areas between the fan-out lines 201 and the power signal lines 202, which facilitates the implementation of the solutions.

As shown in FIG. 12, under a condition that the overlapping lengths L between the power signal line 202 and the fan-out lines 201 in the first fan-out line group P to the M-th fan-out line group P are not equal, for example, when the first section 202a in the power signal line 202 that overlaps the encapsulating area is inverted trapezoid, by gradually increasing the overlapping areas between the openings k1 and the fan-out lines 201 in the first fan-out line group P to the M-th fan-out line group P, the overlapping areas between the power signal line 202 and the fan-out lines 201 in the first fan-out line group P to the M-th fan-out line group P may be the same or decrease gradually, so that the total impedances (the sum of the resistive impedance and the capacitive impedance) of the fan-out lines 201 in the first fan-out line group P to the M-th fan-out line group P change smoothly, and the mura phenomenon of the display panel is reduced or even eliminated.

Still referring to FIG. 13, according to some embodiments of the present application, optionally, in the direction perpendicular to the plane in which the display panel 20 is located, the shape of the first portion b1 of the opening k1 may include a second patterning with a gradually decreasing width. As shown in FIG. 9, the second patterning T2 includes, but is not limited to, a trapezoid, a triangle or an arc. It should be noted that the shape of the other portions of the opening k1 except the first portion b1 may be any shape, such as a circle, a rectangle, a triangle or an irregular shape.

As shown in FIG. 10 and FIG. 12, according to some embodiments of the present application, optionally, the shape of the first portion b1 of the opening k1 may be a rectangle. In the direction perpendicular to the plane in which the display panel 20 is located, the first portion b1 of the opening k1 includes a first edge a1 and a second edge a2 opposite to each other, and the extension direction of the first edge a1 and the second edge a2 may be perpendicular to the extension direction of the fan-out lines 201. It may be understood that in some other examples, alternatively, the first edge of the first portion b1 of the opening k1 may be the edge d1 as shown in FIG. 10 and FIG. 12, and the second edge of the first portion b1 of the opening k1 may be the edge d2 as shown in FIG. 10 and FIG. 12, and in such a case, the extension direction of the first edge d1 and the second edge d2 may be parallel to the extension direction of the fan-out lines 201.

In this way, if the shape of the first portion b1 of the opening k1 is a rectangle, the extension direction of a pair of edges of the first portion b1 is perpendicular to the extension direction of the fan-out lines 201, and the extension direction of the other pair of edges is parallel to the extension direction of the fan-out lines 201, which is beneficial for the adjustment the overlapping areas between the fan-out lines 201 and the power signal line 202 and the implementation of the solutions.

Still referring to FIG. 10, FIG. 12 and FIG. 13, according to some embodiments of the present application, optionally, in the direction perpendicular to the plane in which the display panel 20 is located, the numbers of the openings k1 overlapped by the fan-out lines 201 in the first fan-out line group P to the M-th fan-out line group P may increase gradually.

In this way, since the numbers of the openings k1 overlapped by the fan-out lines 201 in the first fan-out line group P to the M-th fan-out line group P increase gradually, under a condition that the width of the first portion b1 of the opening k1 remains the same or decreases gradually, the overlapping areas between the openings k1 and the fan-out lines 201 in the first fan-out line group P to the M-th fan-out line group P may increase sequentially, so that the overlapping areas between the power signal line 202 and the fan-out lines 201 in the first fan-out line group P to the M-th fan-out line group P are the same or decrease sequentially.

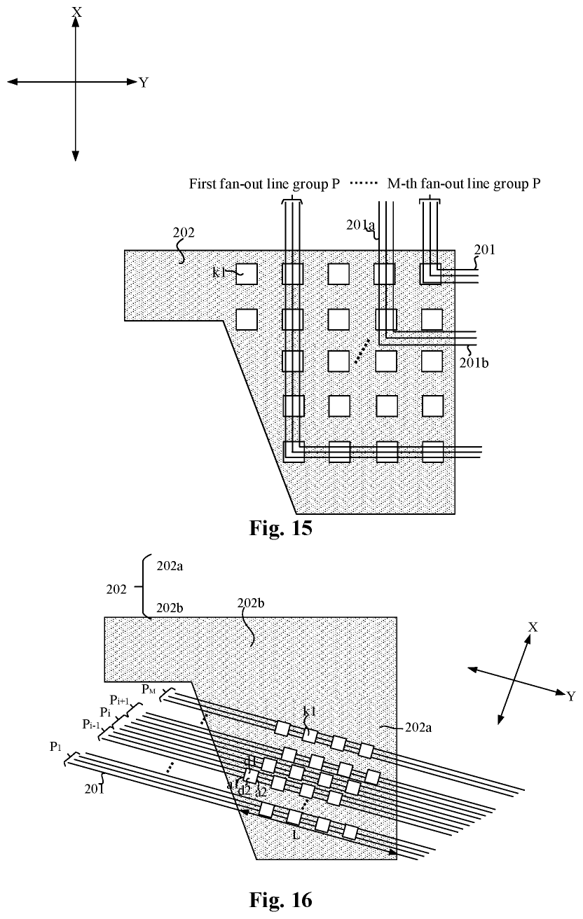

As shown in FIG. 14, according to some embodiments of the present application, optionally, the power signal line 202 may include a plurality of the openings k1 arranged in an array and having a same area. It should be noted that, considering the area differences caused by fabrication errors, if a ration between the areas of two openings k1 is greater than a preset threshold (such as 90% or other values), these areas may be regarded as the same. Among the M fan-out line groups P, the numbers of the openings k1 overlapped by the fan-out lines 201 in the first fan-out line group P to the M-th fan-out line group P are the same. For example, the numbers of the openings k1 overlapped by the fan-out lines 201 in the first fan-out line group P to the M-th fan-out line group P are all n, and n is a positive integer.

It can be seen that in the embodiment shown in FIG. 14, the plurality of the openings k1 on the power signal line 202 can still be arranged in an array or uniformly distributed, and by adjusting the routing of the fan-out lines 201, the numbers of the openings k1 overlapped by the fan-out lines 201 in the first fan-out line group P to the M-th fan-out line group P are the same. In this way, since the areas of the plurality of the openings k1 are equal, the overlapping areas between the openings k1 and the fan-out lines 201 in the first fan-out line group P to the M-th fan-out line group P are the same, and the overlapping areas between the power signal line 202 and the fan-out lines 201 in the first fan-out line group P to the M-th fan-out line group P are the same or decrease gradually, so that the capacitive impedance and the total impedances (the sum of the resistive impedance and the capacitive impedance) of the fan-out lines 201 in the first fan-out line group P to the M-th fan-out line group P change smoothly, and the mura phenomenon of the display panel is reduced or even eliminated.

As shown in FIG. 15, according to some other embodiments of the present application which are different from the embodiment shown in FIG. 14, optionally, among the M fan-out line groups P, the numbers of the openings k1 overlapped by the fan-out lines 201 in the first fan-out line group P to the M-th fan-out line group P may increase gradually.

It can be seen that in the embodiment shown in FIG. 15, the plurality of the openings k1 on the power signal line 202 can still be arranged in an array or uniformly distributed, and by adjusting the routing of the fan-out lines 201, the numbers of the openings k1 overlapped by the fan-out lines 201 in the first fan-out line group P to the M-th fan-out line group P increase gradually. In this way, since the areas of the plurality of the openings k1 are equal, the overlapping areas between the openings k1 and the fan-out lines 201 in the first fan-out line group P to the M-th fan-out line group P increase gradually, and the overlapping areas between the power signal line 202 and the fan-out lines 201 in the first fan-out line group P to the M-th fan-out line group P are the same or decrease gradually, so that the capacitive impedance and the total impedances (the sum of the resistive impedance and the capacitive impedance) of the fan-out lines 201 in the first fan-out line group P to the M-th fan-out line group P change smoothly, and the mura phenomenon of the display panel is reduced or even eliminated.

As shown in FIG. 14 or FIG. 15, in some specific embodiments, optionally, the fan-out lines 201 may include the first sub-fan-out lines 201a extending along the first direction X and the second sub-fan-out lines 201b extending along a second direction Y. In the direction perpendicular to the plane in which the display panel is located, the first sub-fan-out lines 201a and/or the second sub-fan-out lines 201b overlap at least one of the openings k1. That is, the routing of the fan-out lines 201 may be adjusted so that the first sub-fan-out lines 201a overlap at least one of the opening k1, or the second sub-fan-out lines 201b overlap at least one of the openings k1, or even the first sub-fan-out lines 201a and the second sub-fan-out lines 201b overlap different openings k1, respectively, therefore the overlapping areas between the power signal line 202 and the fan-out lines 201 in the first fan-out line group P to the M-th fan-out line group P are the same or decrease gradually. It should be noted that, the first sub-fan-out lines 201a may alternatively extend along other directions than the first direction X, and the second sub-fan-out lines 201b may alternatively extend along other directions except the second direction Y, which is not limited in the embodiments of the present application. In addition, in some embodiments, the fan-out lines 201 may further include third sub-fan-out lines to n-th sub-fan-out lines, and n is an integer greater than or equal to 3. The extension direction of the third sub-fan-out lines to the n-th sub-fan-out lines may be the same as or different from the extension direction of the first sub-fan-out lines 201a or the second sub-fan-out lines 201b.

As shown in FIG. 16, according to some other embodiments of the present application, optionally, the power signal line 202 may include a plurality of the openings k1 arranged in an array, the plurality of the openings k1 are arranged into N opening rows along the first direction X, and each of the opening rows includes at least one of the openings k1. Along the second direction Y intersecting the first direction X, at least one of the openings k1 in the j-th opening row and at least one of the openings k1 in the (j+1)-th opening row are staggered. Herein, the j-th opening row is any one of the N opening rows, 1<j and both j and N are positive integers. In the direction perpendicular to the plane in which the display panel is located, each of the M fan-out line groups P overlaps one of the opening rows.

In this way, since each of the fan-out line groups P corresponds to one of the opening rows, by adjusting the area and/or number of the openings k1 in the opening row corresponding to each of the fan-out line groups P, the overlapping areas between the openings k1 and the fan-out lines 201 in the first fan-out line group P to the M-th fan-out line group P may be the same or increase gradually, and the overlapping areas between the power signal line 202 and the fan-out lines 201 in the first fan-out line group P to the M-th fan-out line group P may be the same or decrease gradually, so that the capacitive impedance and the total impedances (the sum of the resistive impedance and the capacitive impedance) of the fan-out lines 201 in the first fan-out line group P to the M-th fan-out line group P change smoothly, and the mura phenomenon of the display panel is reduced or even eliminated. In addition, the staggered openings are beneficial for adjusting the overlapping areas between the fan-out lines 201 and the power signal lines 202, which facilitates the implementation of the solutions.

Still referring to FIG. 16, optionally, the areas of the plurality of the openings k1 in the N opening rows may be equal. It should be noted that, considering the area differences caused by fabrication errors, if a ration between the areas of two openings k1 is greater than a preset threshold (such as 90% or other values), these areas may be regarded as the same. In this way, since the areas or sizes of the plurality of the openings k1 in the N opening rows are equal, the overlapping areas between the fan-out lines 201 and the power signal line 202 can be adjusted by merely adjusting the number of the openings k1 in the opening row corresponding to each of the fan-out line groups P, which facilitates the design and detection of the overlapping areas between the fan-out lines 201 and the power signal line 202.

Still referring to FIG. 16, according to some embodiments of the present application, optionally, the N-th opening row is located at a side of the first opening row close to the display area AA, and the numbers of the openings k1 in the first opening row to the N-th opening row may be the same. That is, the numbers of the openings k1 overlapped by the fan-out lines 201 in the first fan-out line group P to the M-th fan-out line group P may be the same.

In this way, the overlapping areas between the openings k1 and the fan-out lines 201 in the first fan-out line group P to the M-th fan-out line group P may be the same, and the overlapping areas between the power signal line 202 and the fan-out lines 201 in the first fan-out line group P to the M-th fan-out line group P may be the same or decrease gradually, so that the capacitive impedance and the total impedances (the sum of the resistive impedance and the capacitive impedance) of the fan-out lines 201 in the first fan-out line group P to the M-th fan-out line group P change smoothly, and the mura phenomenon of the display panel is reduced or even eliminated.

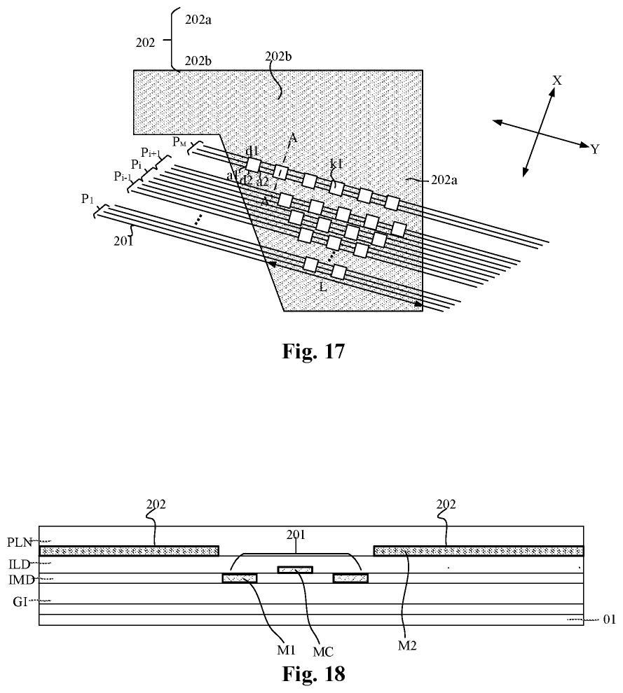

As shown in FIG. 17, according to some other embodiments of the present application which are different from the embodiment shown in FIG. 16, optionally, the numbers of the openings k1 in the first opening row to the N-th opening row may increase sequentially. That is, the numbers of the openings k1 overlapped by the fan-out lines 201 in the first fan-out line group P to the M-th fan-out line group P may increase sequentially.

In this way, the overlapping areas between the openings k1 and the fan-out lines 201 in the first fan-out line group P to the M-th fan-out line group P may increase gradually, and the overlapping areas between the power signal line 202 and the fan-out lines 201 in the first fan-out line group P to the M-th fan-out line group P may be the same or decrease gradually, so that the capacitive impedance and the total impedances (the sum of the resistive impedance and the capacitive impedance) of the fan-out lines 201 in the first fan-out line group P to the M-th fan-out line group P change smoothly, and the mura phenomenon of the display panel is reduced or even eliminated.

Still referring to FIG. 14 to FIG. 17, according to some embodiments of the present application, optionally, the openings k1 may include any polygonal openings or circular openings. The any polygonal openings include, but are not limited to, a triangular opening, a rectangular opening, a trapezoid opening, a parallelogram opening, a pentagonal openings or a N-sided opening, in which N is an integer greater than 5. The circular openings include, but are not limited to, arc openings of any angle, such as a 90° arc opening (a quarter circle), a 180° arc opening (a semi-circle), or a 360° arc opening (a full circle).

As shown in FIG. 16 or FIG. 17, according to some embodiments of the present application, optionally, the opening k1 may be a rectangular opening. In the direction perpendicular to the display plane in which the display panel is located, the rectangular opening includes a first edge a1 and a second edge a2 opposite to each other. The extension direction of the first edge a1 and the second edge a2 of the rectangular opening is perpendicular to the extension direction of the fan-out lines 201. For example, the extension direction of the first edge a1 and the second edge a2 of the rectangular opening is the first direction X, the extension direction of the fan-out lines 201 is the second direction Y, and the first direction X may be perpendicular to the second direction Y. It may be understood that in some other examples, alternatively, the first edge of the rectangular opening may be the edge d1 as shown in FIG. 16 or FIG. 17, and the second edge of the rectangular opening may be the edge d2 as shown in FIG. 16 and FIG. 17, and in such a case, the extension direction of the first edge d1 and the second edge d2 of the rectangular opening may be parallel to the extension direction of the fan-out lines 201.

In this way, if the shape of the first portion b1 of the opening k1 is a rectangle, the extension direction of a pair of edges of the first portion b1 is perpendicular to the extension direction of the fan-out lines 201, and the extension direction of the other pair of edges is parallel to the extension direction of the fan-out lines 201, which is beneficial for the adjustment the overlapping areas between the fan-out lines 201 and the power signal line 202 and the implementation of the solutions.

The film layer distribution of the fan-out lines and the power signal line will be described below with reference to some embodiments of the present application.

As shown in FIG. 18, according to some embodiments of the present application, optionally, the display panel 20 may include a substrate 01, a first metal layer M1, a second metal layer MC and a third metal layer M2 that are stacked and insulating layers arranged between any adjacent metal layers. For example, in the direction perpendicular to the plane in which the display panel 20 is located, a gate insulating layer GI is arranged between the first metal layer M1 and the substrate 01, a capacitive insulating layer IMD is arranged between the second metal layer MC and the first metal layer M1, and an interlayer dielectric layer ILD is arranged between the third metal layer M2 and the second metal layer MC. In the embodiment shown in FIG. 18, the fan-out lines 201 may be located in the first metal layer Ml and the second metal layer MC, and the power signal line 202 may be located in the third metal layer M2. If the fan-out lines 201 are located in the first metal layer M1 and the second metal layer MC, for any adjacent two fan-out lines 201, one of two the fan-out lines 201 may be located in the first metal layer M1, and the other one of the two fan-out lines 201 may be located in the second metal layer MC. As such, on the one hand, the fan-out lines 201 can be arranged more closely in the first direction X, the wiring space is saved; and on the other hand, any adjacent two fan-out lines 201 are arranged in different metal layers, the signals are shielded by the insulating layers arranged between different metal layers, the signal interference between adjacent fan-out lines 201 is reduced.

Alternatively, in some other embodiments, the fan-out lines 201 may be located only in the first metal layer M1. In still other embodiments, the fan-out lines 201 may be located only in the second metal layer MC. If the fan-out lines 201 are located in the second metal layer MC, since the second metal layer MC is usually a Ti/Al/Ti metal stack with low impedance, the resistance drop (IR-drop) on the fan-out lines 201 can be reduced.

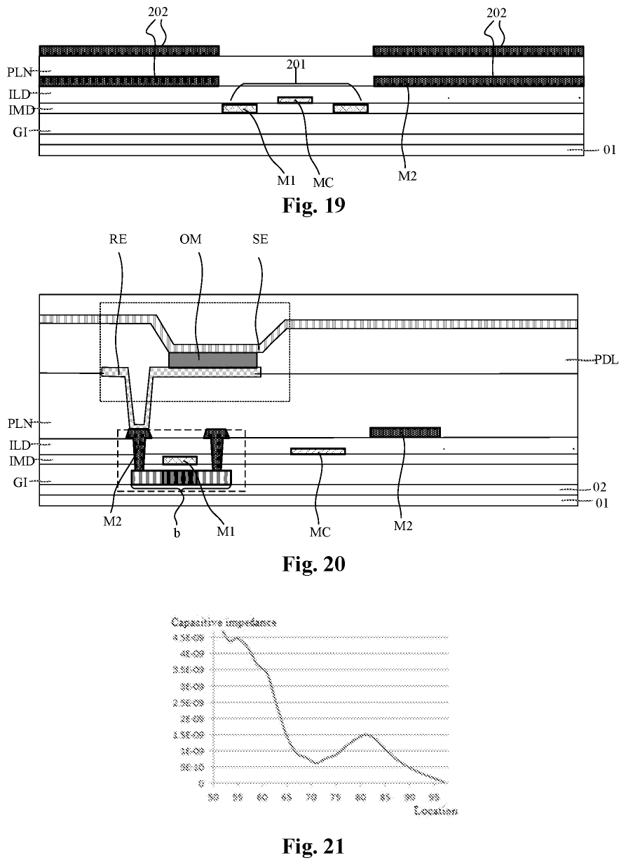

As shown in FIG. 19, according to some other embodiments of the present application which are different from the embodiment shown in FIG. 18, optionally, the display panel 20 may further include a fourth metal layer M3 located at a side of the three metal layer M2 away from the substrate 01. The power signal line 202 may be located in at least one of the third metal layer M2 and the fourth metal layer M3. For example, in the embodiment shown in FIG. 19, the power signal lines 202 may be located in both of the third metal layer M2 and the fourth metal layer M3. In the direction perpendicular to the plane in which the display panel 20 is located, the power signal line 202 located in the third metal layer M2 may at least partially overlap the power signal line 202 located in the fourth metal layer M3, and the power signal line 202 located in the third metal layer M2 may be electrically connected to the power signal line 202 located in the fourth metal layer M3 through a via (not shown).

It may be understood that when the display panel 20 includes the fourth metal layer M3, the fan-out lines 201 may be located in the first metal layer M1 and the second metal layer MC, alternatively, the fan-out lines 201 may be located only in the first metal layer M1 or the second metal layer MC.

In order to facilitate the understanding, each of the above film layers will be described below in conjunction with the partial schematic sectional views of the display area of the OLED display panel.

As shown in FIG. 20, according to some embodiments of the present application, optionally, the display panel 20 may include a substrate 01, a buffer layer 02, a first metal layer M1, a second metal layer MC and a third metal layer M2 that are stacked. An active layer b is arranged between the first metal layer M1 and the buffer layer 02. Insulating layers are arranged between any adjacent metal layers and between the active layer b and the first metal layer M1. Exemplarily, a gate insulating layer GI is arranged between the first metal layer M1 and the active layer b, a capacitive insulating layer IMD is arranged between the second metal layer MC and the first metal layer M1, and an interlayer dielectric layer ILD is arranged between the third metal layer M2 and the second metal layer MC. In addition, the display panel 20 may further include a planarization layer PLN and a pixel defining layer PDL, and the light-emitting element may include an anode RE, a light-emitting layer OM and a cathode SE that are stacked. The display panel 20 may include a thin film transistor T and a storage capacitor. The active region of the thin film transistor T may be located in the active layer b, the gate of the thin film transistor T may be located in the first metal layer M1, and the source and/or drain of the thin film transistor T may be located in the third metal layer M2. The first electrode plate of the storage capacitor may be located in the first metal layer M1, and the second electrode plate of the storage capacitor may be located in the second metal layer MC.

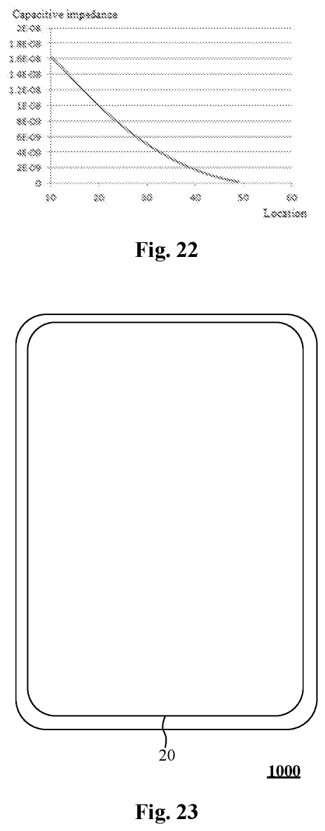

FIG. 21 shows a schematic graph of the capacitive impedances of the fan-out lines located at different locations of the display panel under a condition that the overlapping relationships between the fan-out lines and the openings on the power signal lines are not adjusted. FIG. 22 shows a schematic graph of the capacitive impedances of the fan-out lines located at different locations of the display panel under a condition that the overlapping relationships between the fan-out lines and the openings on the power signal lines have been adjusted. For example, in FIG. 21 and FIG. 22, the abscissa represents different locations in the display panel, and the ordinate represents the capacitive impedances. As shown in FIG. 21, under a condition that the overlapping relationships between the fan-out lines and the openings on the power signal lines are not adjusted, in the direction perpendicular to the plane in which the display panel is located, since the overlapping areas between the fan-out lines located at different locations or adjacent locations and the power signal lines change abruptly, the capacitive capacitances generated between the fan-out lines located at different locations or adjacent locations and the power signal lines change abruptly, causing that the mura phenomenon occurs for the display panel, such as vertical stripes in the display panel. As shown in FIG. 22, by contrast, by adjusting the overlapping relationships between the fan-out lines and the openings on the power signal lines, such as adjusting the location and/or size of the openings on the power signal lines, or adjusting the routing of the fan-out lines, the overlapping areas between the power signal lines and the fan-out lines in the adjacent fan-out line groups decrease sequentially, so that the capacitive impedances generated between the power signal lines and the fan-out lines in the adjacent fan-out line groups change smoothly, therefore a sudden change of the capacitive impedances generated between the power signal lines and the fan-out lines located at different locations or adjacent locations is avoided, and the mura phenomenon of the display panel is reduced or even eliminated.

Based on the display panel 20 according to the above embodiments, correspondingly, the present application further provides a display apparatus including the display panel according to the present application. Please refer to FIG. 23, which shows a schematic structural diagram of a display apparatus according to the embodiments of the present application. The display apparatus 1000 as shown in FIG. 23 includes the display panel 20 according to any of the above embodiments of the present application. For example, the display apparatus 1000 is illustrated in a context in which the embodiment as shown in FIG. 23 includes a mobile phone. It may be understood that the display apparatus according to the embodiments of the present application may be a wearable product, a computer, a TV, a vehicle-mounted display device, or other display devices with display functions, which is not specifically limited in the present application.

It should be understood that the specific structures of the pixel circuit and the layout structure of the display panel provided in the accompanying drawings of the embodiments of the present application are only examples, and not intended to limit the present application. In addition, the above embodiments of present application may be combined without conflict.

The above embodiments of the present application do not exhaustively describe all the details and do not limit the present application to only the specific embodiments described. Obviously, many modifications and variations can be made based on the above description. These embodiments are selected and specifically described in the description to better explain the principles and practical applications of the present application, so that those skilled in the art can make good use of the present application and make modifications based on the present application. The present application is limited only by the claims, along with their full scope and equivalents.

What is claimed is:

1. A display panel comprising a display area, and fan-out lines and a power signal line located in a non-display area, the power signal line comprising openings overlapping at least a part of the fan-out lines;
in a direction perpendicular to a plane in which the display panel is located, the fan-out lines overlapping the power signal line comprising M fan-out line groups arranged in sequence along a first direction, each of the fan-out line groups comprising at least one of the fan-out lines overlapping the power signal line, M being a positive integer;
among the M fan-out line groups, a (i−1)-th fan-out line group being located at a side of an i-th fan-out line group away from the display area, a (i+1)-th fan-out line group being located at a side of the i-th fan-out line group close to the display area; the (i−1)-th fan-out line group comprising the fan-out lines with a length Lᵢ₋₁, the i-th fan-out line group comprising the fan-out lines with a length L, the (i+1)-th fan-out line group comprising the fan-out lines with a length Lᵢ₊₁, and Lᵢ₋₁>Lᵢ>Lᵢ₋₁; and
in the direction perpendicular to the plane in which the display panel is located, an overlapping area between the fan-out lines with the length L₋₁ and the power signal line being Sᵢ₋₁, an overlapping area between the fan-out lines with the length Lᵢ and the power signal line being Sᵢ, and an overlapping area between the fan-out lines with the length Lᵢ₊ᵢ and the power signal line being Sᵢ₊₁, Sᵢ₋₁≥Sᵢ≥Sᵢ₊₁, wherein 2≤i≤M−1.

2. The display panel of claim 1, wherein among the M fan-out line groups, lengths of the fan-out lines in a first fan-out line group to a M-th fan-out line group decrease sequentially;
in the direction perpendicular to the plane in which the display panel is located, overlapping areas between the power signal line and the fan-out lines in the first fan-out line group to the M-th fan-out line group are the same; or
in the direction perpendicular to the plane in which the display panel is located, the overlapping areas between the power signal line and the fan-out lines in the first fan-out line group to the M-th fan-out line group decrease gradually.

3. The display panel of claim 1, wherein the power signal line comprises Q openings extending along the first direction, and Q is a positive integer;
in the direction perpendicular to the plane in which the display panel is located, all of the fan-out lines in the M fan-out line groups overlap the Q openings; and
along a direction from the (i+1)-th fan-out line group to the (i−1)-th fan-out line group, a width of each of the Q openings remains the same or decreases gradually.

4. The display panel of claim 3, wherein in the direction perpendicular to the plane in which the display panel is located, the fan-out lines in the M fan-out line groups overlap a first portion of each of the Q openings; and
in the direction perpendicular to the plane in which the display panel is located, a shape of the first portion of the opening comprises a first patterning with a constant width or a second patterning with a gradually decreasing width, the first patterning comprises a rectangle, a wavy shape or a zigzag shape, the second patterning comprises a trapezoid, a triangle or an arc, and the width is a minimum distance of the opening along a second direction intersecting the first direction.

5. The display panel of claim 1, wherein the power signal line comprises P openings extending along the first direction, the P openings are arranged in sequence along a second direction intersecting the first direction, and P is a positive integer; and
along the second direction, areas or lengths of at least a part of the P openings decrease or increase gradually.

6. The display panel of claim 5, wherein along a direction from the (i+1)-th fan-out line group to the (i−1)-th fan-out line group, a width of each of the openings remains the same or decreases gradually.

7. The display panel of claim 6, wherein in the direction perpendicular to the plane in which the display panel is located, a shape of a first portion of the opening comprises a first patterning with a constant width or a second patterning with a gradually decreasing width, the first patterning comprises a rectangle, a wavy shape or a zigzag shape, and the second patterning comprises a trapezoid, a triangle or an arc.

8. The display panel of claim 5, wherein in the direction perpendicular to the plane in which the display panel is located, numbers of the openings overlapped by the fan-out lines in a first fan-out line group to a M-th fan-out line group increase gradually.

9. The display panel of claim 3, wherein a shape of a first portion of the opening is a rectangle, and in the direction perpendicular to the plane in which the display panel is located, the first portion comprises a first edge and a second edge opposite to each other, and an extension direction of the first edge and the second edge is perpendicular or parallel to an extension direction of the fan-out lines.

10. The display panel of claim 1, wherein the power signal line comprises a plurality of the openings arranged in an array and having a same area; and
among the M fan-out line groups, numbers of the openings overlapped by the fan-out lines in a first fan-out line group to a M-th fan-out line group are the same or increase gradually.

11. The display panel of claim 1, wherein the power signal line comprises a plurality of the openings arranged in an array, the plurality of the openings are arranged into N opening rows along the first direction, and each of the opening rows comprises at least one of the openings;
along a second direction intersecting the first direction, at least one of the openings in a j-th opening row and at least one of the openings in a (j+1)-th opening row are staggered, l<j≤N−1 and
in the direction perpendicular to the plane in which the display panel is located, each of the M fan-out line groups overlaps one of the opening rows.

12. The display panel of claim 11, wherein areas of the plurality of the openings in the N opening rows are equal.

13. The display panel of claim 11, wherein a N-th opening row is located at a side of a first opening row close to the display area, and numbers of the openings in the first opening row to the N-th opening row are the same or increase sequentially.

14. The display panel of claim 10, wherein the openings comprise any polygonal openings or circular openings.

15. The display panel of claim 10, wherein the openings are rectangular openings, and in the direction perpendicular to the plane in which the display panel is located, each of the rectangular openings comprises a first edge and a second edge opposite to each other, an extension direction of the first edge and the second edge is perpendicular to an extension direction of the fan-out lines,
or the extension direction of the first edge and the second edge is parallel to the extension direction of the fan-out lines.

16. The display panel of claim 11, wherein the openings are rectangular openings, and in the direction perpendicular to the plane in which the display panel is located, each of the rectangular openings comprises a first edge and a second edge opposite to each other, an extension direction of the first edge and the second edge is perpendicular to an extension direction of the fan-out lines,
or the extension direction of the first edge and the second edge is parallel to the extension direction of the fan-out lines.

17. The display panel of claim 1, wherein the fan-out lines comprise first sub-fan-out lines extending along the first direction and second sub-fan-out lines extending along a second direction, and in the direction perpendicular to the plane in which the display panel is located, the first sub-fan-out lines and/or the second sub-fan-out lines overlap at least one of the openings.

18. The display panel of claim 1, wherein the display panel comprises a substrate, a first metal layer, a second metal layer and a third metal layer that are stacked and insulating layers arranged between any adjacent metal layers; and
the fan-out lines are located in at least one of the first metal layer and the second metal layer, and the power signal line is located in the third metal layer.

19. The display panel of claim 1, wherein the display panel comprises a substrate, a first metal layer, a second metal layer, a third metal layer and a fourth metal layer that are stacked and insulating layers arranged between any adjacent two metal layers; and
the fan-out lines are located in at least one of the first metal layer and the second metal layer, and the power signal line is located in at least one of the third metal layer and the fourth metal layer.

20. A display apparatus comprising a display panel, the display panel comprising a display area, and fan-out lines and a power signal line located in a non-display area, the power signal line comprising openings overlapping at least a part of the fan-out lines;
in a direction perpendicular to a plane in which the display panel is located, the fan-out lines overlapping the power signal line comprising M fan-out line groups arranged in sequence along a first direction, each of the fan-out line groups comprising at least one of the fan-out lines overlapping the power signal line, M being a positive integer;
among the M fan-out line groups, a (i−1)-th fan-out line group being located at a side of an i-th fan-out line group away from the display area, a (i+1)-th fan-out line group being located at a side of the i-th fan-out line group close to the display area; the (i−1)-th fan-out line group comprising the fan-out lines with a length Lᵢ₋₁, the i-th fan-out line group comprising the fan-out lines with a length Li, the (i+1)-th fan-out line group comprising the fan-out lines with a length Lᵢ₊₁, and Lᵢ₋₁>Lᵢ>L_{i+L}: and
in the direction perpendicular to the plane in which the display panel is located, an overlapping area between the fan-out lines with the length L₋₁ and the power signal line being Sᵢ₋₁, an overlapping area between the fan-out lines with the length Lᵢ and the power signal line being Sᵢ, and an overlapping area between the fan-out lines with the length Lᵢ₊₁ and the power signal line being Sᵢ₊₁, Sᵢ₋₁≥Sᵢ≥Sᵢ₊₁, wherein 2≤i≤M−1.
